(19) United States
(12) Patent Application Publication
(10) Pub. No.: US 2015/0332950 A1
(43) Pub. Date: Nov. 19, 2015

(54) ON-END EFFECTOR MAGNETIC WAFER CARRIER ALIGNMENT

(71) Applicant: Applied Materials, Inc., Santa Clara, CA (US)

(72) Inventors: John Mazzocco, San Jose, CA (US); Daniel Greenberg, San Jose, CA (US); Bryan Alwin Yaya, Fremont, CA (US)

(21) Appl. No.: 14/280,519

(22) Filed: May 16, 2014

(51) Int. Cl. H01L 21/683; B25J 15/06

(52) U.S. Cl. CPC H01L 21/683; B25J 15/0608; Y10S 901/30

(57) ABSTRACT

Embodiments include methods and apparatuses for transferring and aligning a carrier ring. In an embodiment, a method includes lifting the carrier ring from a first location with a robot arm that includes an end effector wrist and an end effector. Front dowel pins and rear dowel pins are coupled to the end effector. In an embodiment, the end effector wrist includes a plunger that has a gripping device. Embodiments include securing the plunger to the carrier ring with the gripping device and extending the plunger out from the end effector wrist until the carrier ring contacts the front dowel pins. Thereafter, the carrier ring is transferred from the first location to the second location. The plunger and the carrier ring are then retracted until the rear dowel pins engage an alignment notch and an alignment flat on the carrier ring.

### BACKGROUND

1) Field

Embodiments of the present invention pertain to the field of semiconductor processing and, in particular, to methods and apparatuses for transferring and aligning carrier rings.

2) Description of Related Art

Substrates are transferred from a front opening unified pod (FOUP) to a processing tool by a wafer handling robot. Substrates are typically not aligned prior to being inserted into a FOUP. As such, prior to transferring the substrate to the processing tool, the substrate is aligned at an alignment station in order to properly orient the substrate for processing. The use of an alignment station increases the footprint of the tool and requires an additional processing operation during the transfer of the substrate from the FOUP to the processing tool. After the substrate is processed by the tool, the wafer handling robot returns the substrate to the FOUP.

When the substrate is circular, such as a commercially available silicon wafer, the angular rotation of the substrate is not critical for replacing the substrate into the FOUP. However, when the substrate is not circular and, therefore, does not have a constant diameter, the angular rotation of the substrate becomes critical. If such a substrate is returned to the FOUP improperly oriented, then the diameter of the substrate passing through the opening may be greater than the width of the FOUP's opening and will not fit. As such, it may be necessary to orient the substrate at an alignment station after processing as well.

### SUMMARY

Embodiments of the invention include a method of aligning a carrier ring with a robot arm. The robot arm may include an end effector that extends outward from an end-effector wrist. The end effector may include front dowel pins and rear dowel pins. The robot arm may also include a plunger that extends and retracts from the end effector wrist. In an embodiment, the method includes lifting a carrier ring with the end effector. The method may also include contacting the carrier ring with the plunger. In an embodiment, the plunger includes a gripping device. The method may also include extending the plunger until the carrier ring contacts the front dowel pins. According to an embodiment, the method further includes transferring the carrier ring from a first location to a second location after the carrier ring has been brought into contact with the front dowel pins. In an embodiment, the method includes retracting the plunger and the carrier ring back towards the end effector wrist until the carrier ring contacts the rear dowel pins. In an embodiment, a first rear dowel pin contacts an alignment notch in the carrier ring and a second rear dowel pin contacts an alignment flat in the carrier ring.

An embodiment of the invention also includes a robot arm used for aligning a carrier ring and transferring the carrier ring from a first location to a second location. In an embodiment, the robot arm includes an end effector wrist. The robot arm may also include an end effector that extends outward from the end effector wrist. In an embodiment, the end effector includes rear dowel pins positioned on the end effector proximate to the end effector wrist and front dowel pins positioned on the end effector proximate to the end of the end effector opposite the rear dowel pins. In an embodiment, the end effector wrist includes a plunger that is extendable out from the end effector wrist. Embodiments include a plunger that further includes a gripping device. For example, the gripping device may be a magnet, such as a permanent magnet or an electromagnet, or a mechanical gripping device, such as a clamp.

### BRIEF DESCRIPTION OF THE DRAWINGS

FIG. 1 is an illustration of a carrier ring assembly that includes a carrier ring, an adhesive backing and a substrate, in accordance with an embodiment.

FIG. 2A is a cross-sectional illustration of a front opening unified pod (FOUP) that stores carrier ring assemblies, in accordance with an embodiment.

FIG. 2B is a cross-sectional illustration of FIG. 2B along the line B-B, in accordance with an embodiment.

FIG. 3 is an illustration of a robot arm, in accordance with an embodiment.

FIG. 4 is an illustration of a flowchart representing operations in a method for transferring and aligning a carrier ring with a robot arm, in accordance with an embodiment.

FIGS. 5A-5D illustrate schematic block diagrams of a process for transferring and aligning a carrier ring with a robot arm, in accordance with an embodiment.

FIG. 6 is an illustration of a block diagram of a processing tool, in accordance with an embodiment of the invention.

FIGS. 7A-7C illustrate cross-sectional views of a semiconductor wafer including a plurality of integrated circuits during a method of dicing a semiconductor wafer, in accordance with an embodiment of the invention.

FIG. 8 illustrates a block diagram of an exemplary computer system, in accordance with an embodiment.

### DETAILED DESCRIPTION

Methods and apparatuses used for aligning a carrier ring with robot arm are described in accordance with various embodiments. In the following description, numerous specific details are set forth, such as substrates supported by a carrier ring, FOUPs, and end effectors in order to provide a thorough understanding of embodiments of the present invention. It will be apparent to one skilled in the art that embodiments of the present invention may be practiced without these specific details. In other instances, well-known aspects are not described in detail in order to not unnecessarily obscure embodiments of the invention. Furthermore, it is to be understood that the various embodiments shown in the Figures are illustrative representations and are not necessarily drawn to scale.

In an embodiment, a robot arm includes an end effector that extends outward from an end effector wrist. The end effector includes front dowel pins and rear dowel pins used for securing and aligning a carrier ring during the transfer of the carrier ring between a first location and a second location. The end effector wrist may include a plunger. In an embodiment, the plunger includes a gripping device, such as a magnet.

In an embodiment, the end effector lifts the carrier ring up from a first location. The plunger is then extended towards the carrier ring. The plunger contacts an edge of the carrier ring and pushes the carrier ring away from end effector wrist until the carrier ring is secured between the plunger and the front dowel pins. In an embodiment, the end effector may transfer the carrier ring to a processing tool while maintaining the three points of contact. In embodiments the plunger is retracted. A gripping device engages the carrier ring and pulls the carrier ring towards the rear dowel pins. One of the rear dowel pins engages an alignment flat formed on the carrier ring, and the second rear dowel pin engages an alignment notch formed on the carrier ring. After the carrier ring engages the rear dowel pins, the gripping device may release the carrier ring.

The use of a robot arm according to embodiments of the invention allows for improved alignment of a carrier ring assembly. Ensuring proper alignment of the carrier ring assembly allows the carrier ring to be inserted into narrow openings, such as the opening of a FOUP. Additionally, proper alignment enhances the effectiveness of substrate processing operations. For example, proper alignment of the carrier ring ensures that a shadow ring used during a substrate dicing operation protects an adhesive backing tape used to support the substrate. If the adhesive backing tape is unprotected, then the processing, such as plasma processing, may damage the backing tape and reduce yield. Furthermore, a robot arm that includes an end effector with front and rear dowel pins, and an end effector wrist that includes a plunger, is able to align the carrier ring assembly while the carrier ring is being transferred between locations. Accordingly, extra processing operations and tools, such as an alignment tool, may be omitted when using embodiments of the invention.

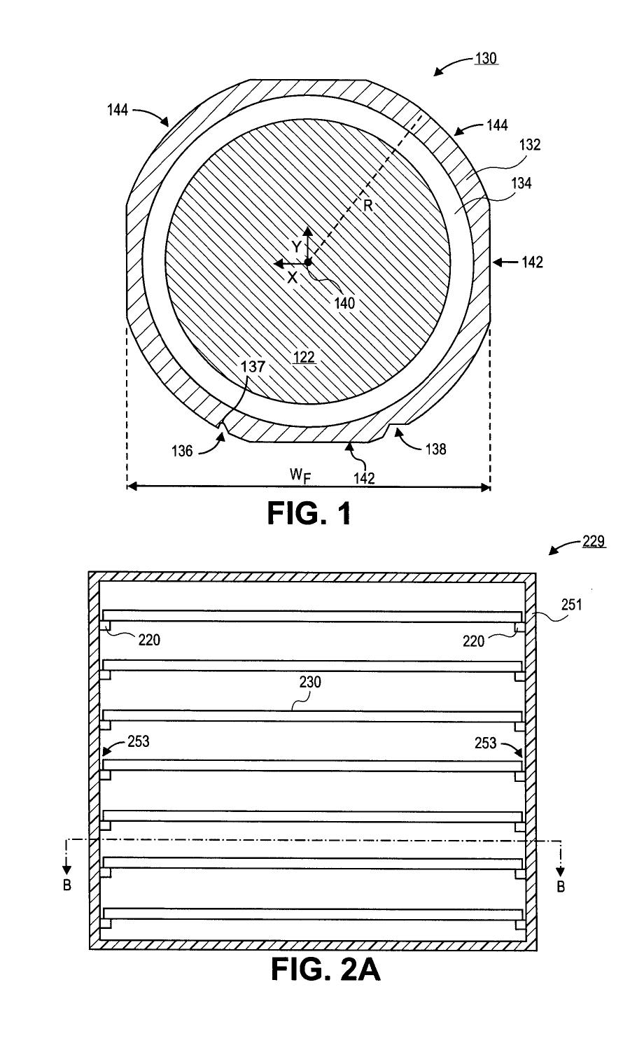

Referring now to FIG. 1, a carrier ring assembly 130 is shown according to an embodiment. In an embodiment, the carrier ring assembly 130 includes a carrier ring 132, an adhesive backing tape 134 and a substrate 122. The layer of adhesive backing tape 134 is surrounded by the carrier ring 132. The substrate 122 is supported by the backing tape 134. In an embodiment, the carrier ring 132 may be a metallic material. For example, the carrier ring 132 is a stainless steel. Embodiments include a carrier ring 132 that is formed from a magnetic material. In an additional embodiment, the carrier ring 132 is a non-metallic material, such as a polymeric material or a resin. In an embodiment, the substrate 122 is a commercially available silicon wafer, such as a 300 mm silicon wafer. Additional embodiments include a carrier ring assembly 130 sized for carrying a larger or smaller substrate, such as 200 mm or 450 mm substrates. Substrate 122 may have a plurality of individual device dies (not shown) that each include integrated circuitry formed thereon.

While specific reference is made herein to carrier ring assemblies 130 that include substrates 122 that are wafers, embodiments are not so limited. Substantially similar methods and apparatuses to those described herein may be used to align a carrier ring assembly 130 that support substrates other than a single silicon wafer. For example, carrier ring assemblies 130 for carrying multiple substrates may be utilized according to embodiments of the invention. For example, a carrier ring assembly 130 utilized for processing light emitting diodes (LEDs) formed on a plurality of sapphire substrates may be aligned with a robot arm according to an embodiment of the invention.

In an embodiment, carrier ring 132 has one or more flat edges 142. As shown in FIG. 1, the carrier ring 132 includes four flat edges 142. In an embodiment, the width of the carrier ring 132 between opposing flat edges W_{F} is approximately 380 mm, though embodiments are not limited to such configurations. For example, a carrier ring 132 for carrying a larger substrate 122 may have a width W_{F} greater than 380 mm. Embodiments include a carrier ring 132 that has rounded edges 144 that are formed between flat edges 142. In an embodiment, the rounded edges 144 are circular arcs with an origin at the center 140 of the carrier ring assembly 130. In an embodiment the radius R of the rounded edges 144 may be approximately 200 mm, though embodiments are not limited to such configurations. For example, a carrier ring 132 for carrying a larger substrate 122 may have rounded edges 144 that have a radius R greater than 200 mm. Accordingly, the width of the carrier ring 132 is variable depending on the angular orientation about the center 140. For example, the width between two points on opposite sides of the carrier ring 132 along the rounded edges 144 (i.e., 2R) is larger than the width W_{F} between two flat edges 142. The difference in the widths presents additional problems that are not encountered in substantially circular substrates. For example, an opening in a FOUP may be sized to receive a carrier ring 132 that is oriented such that its narrowest width (i.e., W_{F} between the flat edges 142) fits through the FOUP opening.

In order to ensure that the carrier ring 132 is properly oriented and able to fit through a FOUP opening, the carrier ring 132 includes an alignment flat 138 and an alignment notch 136 formed on opposite sides of a bottom flat edge 142. In embodiments, the alignment flat 138 runs parallel to the bottom flat edge 142. The alignment notch 136 is sized to receive a dowel pin (described in greater detail below) that is located on an end effector. In an embodiment, the apex 137 of the alignment notch 136 is a rounded surface. In an embodiment, the apex 137 has a radius of curvature approximately equal to, or smaller than, the radius of the dowel pin. By way of example, the radius of curvature of the apex 137 may be approximately 1.5 mm or less. In an embodiment, the apex 137 is not curved and meets at angle. By way of example, the angle of the notch may be approximately 60°. Since the radius of curvature of the apex 137 is approximately equal, to or smaller than, the radius of the dowel pin, the dowel pin will be constrained from moving in the X-direction once engaged by the alignment notch 136. As used herein, the dowel pin is engaged with the alignment notch 136 when the dowel pin is in contact with the apex 137, or when the dowel pin is constrained from moving in the X-direction by two or more points of contact along the alignment notch 136.

In order to properly align the carrier ring, the apex 137 of the alignment notch 136 is located at substantially the same position in the Y-direction as the alignment flat 138. In addition to knowing the location of the center point 140 in the X and Y-directions, the alignment notch 136 and the alignment flat 138 allow for the angular rotation of the carrier ring 132 about the center point 140 to be known as well. The alignment notch 136 and the alignment flat 138 provide the angular rotation because their positions relative to the center point 140 is known, and their position is distinguishable from other points on the circumference of the carrier ring 132. In contrast, contacting the carrier ring 132 with two dowel pins along opposing curved surfaces would only be able to provide information regarding the position of the carrier ring in the X and Y-directions since the curved edges 144 are uniform. Accordingly, embodiments of the present invention provide additional information about the angular orientation of the carrier ring 132 that is not obtainable with an end effector that does not include dowel pins for engaging the alignment notch 136 and the alignment flat 138, according to embodiments of the invention.

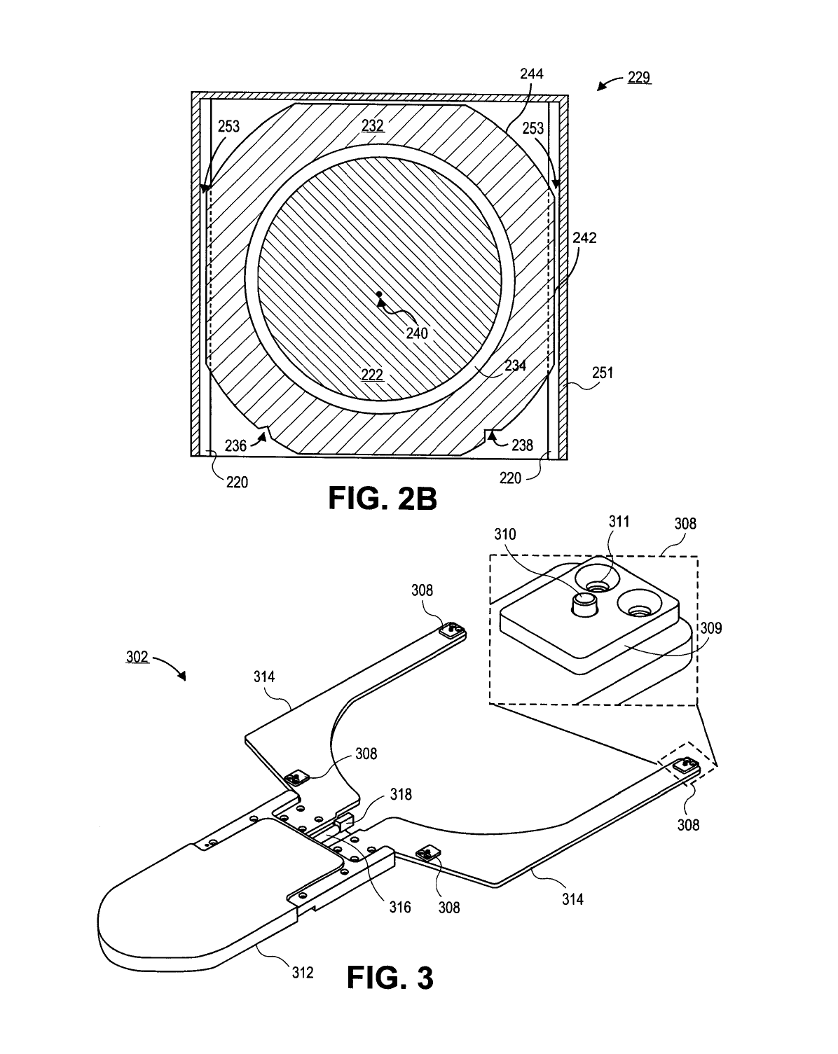

Referring now to FIG. 2A, a cross-sectional illustration of a plurality of carrier ring assemblies 230 stored in a FOUP 229 is shown. Slots 220 formed along the sidewalls 251 of the FOUP 229 support the edges of the carrier ring assembly 230. In embodiments, there is a space 253 between the sidewall 251 and the sides of the carrier ring assemblies 230. Referring now to FIG. 2B, which illustrates the cross-sectional view along line B-B, it is shown that the carrier ring assemblies 230 are inserted into the FOUP 229 with the flat edges 242 oriented approximately parallel to the side walls 251. In an embodiment the width of the FOUP opening is greater than the width W_{F} of carrier ring 232 between the flat edges 242 and smaller than the width of the carrier ring between opposing rounded edges 144 (i.e., 2R). As such, an improperly oriented carrier ring 232 will not fit through the opening of the FOUP. For example, the space 253 between the flat edge 242 of the carrier ring 232 and the sidewall 251 may be approximately 2.0 mm or less. In embodiments, such as the one shown, where the larger width between opposing rounded edges 244 may be 20 mm or more greater than the width W_{F} between flat edges 242, an improperly oriented carrier ring 232 will not fit through the opening of the FOUP 229.

As such, the flat edges 242 need to be aligned roughly parallel to the sidewalls 251 in order to fit through the opening. By way of example, the carrier ring 232 will fit through the opening in the FOUP 229 when the flat edges 242 are oriented within approximately 1.5° of parallel with the sidewalls 251 of the FOUP 229. Accordingly, embodiments include a carrier ring 232 that needs to be aligned prior to being inserted into a FOUP 229, whereas a round wafer would fit through the opening in the FOUP 229 regardless of its rotational orientation due to its uniform diameter. Additionally, a processing tool may require precise angular alignment in order to properly process the substrate 222 on the carrier ring assembly 230. For example, when a dicing operation is performed, the orientation of the carrier ring may need to be known in order to accurately dice along scribe lines formed between the individual die on the substrate 222. Knowing the orientation of the carrier ring also ensures that a shadow ring used during a dicing operation completely covers and protects the adhesive backing tape 234 from processing conditions that may damage the backing tape 234.

Accordingly, embodiments include a robot arm 302 that can be used for aligning a carrier ring in the X-direction, the Y-direction, and in its angular rotation about the center point 240. In an embodiment the alignment process is implemented while transferring the carrier ring 232 from a first location to a second location. For example, the robot arm 302 may align a carrier ring 232 while transferring the carrier ring 232 from a processing tool to a FOUP. Alternatively, the robot arm 302 may aligning a carrier ring 232 while transferring the carrier ring 232 from a FOUP to a processing tool. In such embodiments, additional alignment tools and alignment processes are not necessary according to embodiments described herein because the alignment is performed during the transfer process. Therefore, throughput is increased by reducing processing operations that cannot be performed concurrent with the transfer operation, and the footprint of the processing tool can be reduced by removing the extraneous alignment tool.

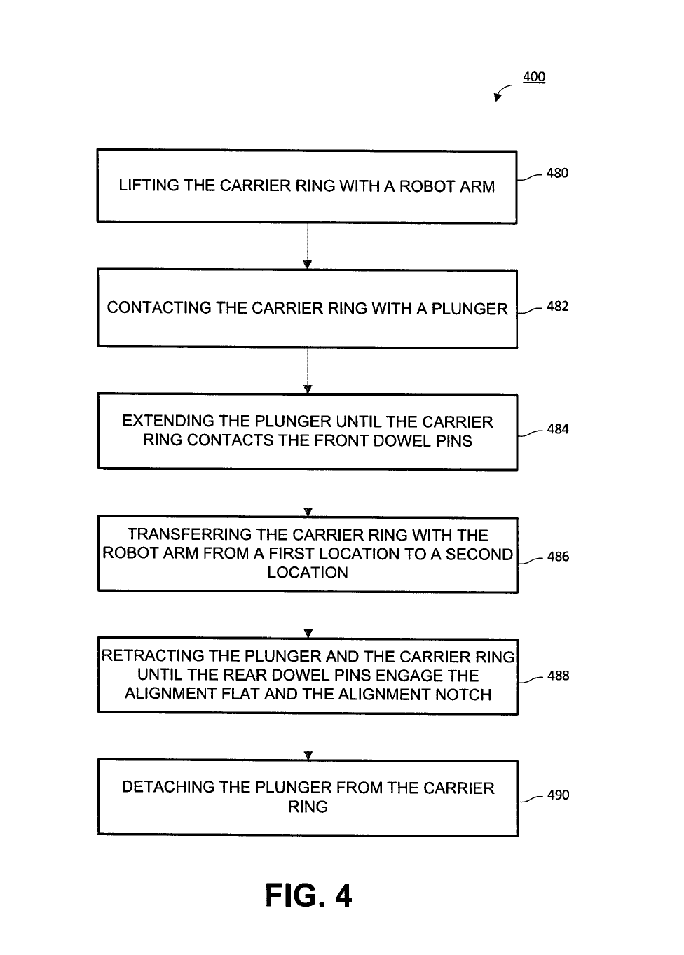

Referring now to FIG. 3, a robot arm 302 according to an embodiment is shown. In an embodiment, robot arm 302 includes an end effector wrist 312. The end effector wrist 312 couples the robot arm 302 to a wafer handling robot (not shown). For example, the wafer handling robot may be a selective compliance articulated robot arm (SCARA) or any other wafer handling robot known in the art. In an embodiment, an end effector 314 is coupled to the end effector wrist 312. As shown, the end effector 314 includes two separate prongs that extend outward from the end effector wrist, though embodiments are not limited to such configurations. For example, both prongs of the end effector 314 may be formed as a single unified component. Embodiments of the invention include an end effector 314 that is formed from a rigid material. For example, the end effector 314 may be a metallic material, a ceramic material, or a composite material. In embodiments of the invention, the end effector 314 may be made from aluminum, nickel plated aluminum, anodized aluminum, alumina, or carbon fiber.

Embodiments of the invention utilize a plurality of dowel pin assemblies 308 to secure the carrier ring during a transfer from a first location to a second location and to perform the aligning processes. In an embodiment a plurality of dowel pin assemblies 308 are formed on a top surface of the end effector 314. In an embodiment, front dowel pin assemblies 308 are formed proximate to the end of the end effector 314 furthest from the end effector wrist 312, and rear dowel pin assemblies 308 are formed proximate to the end of the end effector 314 closest to the end effector wrist 312. According to an embodiment, the front dowel pin assemblies are substantially similar to the rear dowel pin assemblies. As show in the zoomed in illustration of a dowel pin assembly 308, each assembly includes a dowel pin 310. In an embodiment, the dowel pin may extend up from a pad 309. In an embodiment, the carrier ring assembly 230 rests on a top surface of the pads 309. According to an embodiment of the invention, the dowel pins 310 extend a height above pads 309 that is approximately equal to or greater than the thickness of a carrier ring assembly 230. For example, the dowel pins 310 may extend above the pads 309 by 1.5 mm or more. In an embodiment, the dowel pins have a radius that is approximately equal to or greater than the radius of curvature of the apex 137 of the alignment notch 136. By way of example, the radius of the dowel pins 310 is approximately 1.5 mm or greater. In the embodiment illustrated in FIG. 3, the dowel pin assemblies 308 are coupled to the end effector 314 by fasteners 311. For example, fasteners 311 may include screws, bolts, or the like. In an embodiment, dowel pin assemblies 308 and the end effector 314 are a single continuous component formed from a single material. According to an additional embodiment, a dowel pin 310 may extend up directly from the end effector 314 and the pad 309 is omitted.

In an embodiment, the robot arm 302 includes a plunger 316. The plunger 316 is coupled to the end effector wrist 312. In an embodiment the plunger 316 is located between the prongs of the end effector 314. The plunger 316 can be extended out from the end effector wrist 312. By way of example, the plunger 316 is a hydraulic piston. Plunger 316 also includes a griping device 318. The gripping device 318 allows the plunger 316 to securely attach to an edge of the carrier ring 232. In an embodiment, the gripping device 318 is a magnet. By way of example, the magnet may be a permanent magnet or an electromagnet. In an embodiment, the gripping device 318 may include a mechanical gripping mechanism. A mechanical gripping mechanism allows the end effector 302 to perform the alignment functions on a carrier ring 232 that is formed from a non-magnetic material, such as a polymer. By way of example, a mechanical gripping mechanism may include a clamp. Though shown as two distinct components, it is appreciated that the plunger 316 and the gripping device 318 can be integrated into a single component.

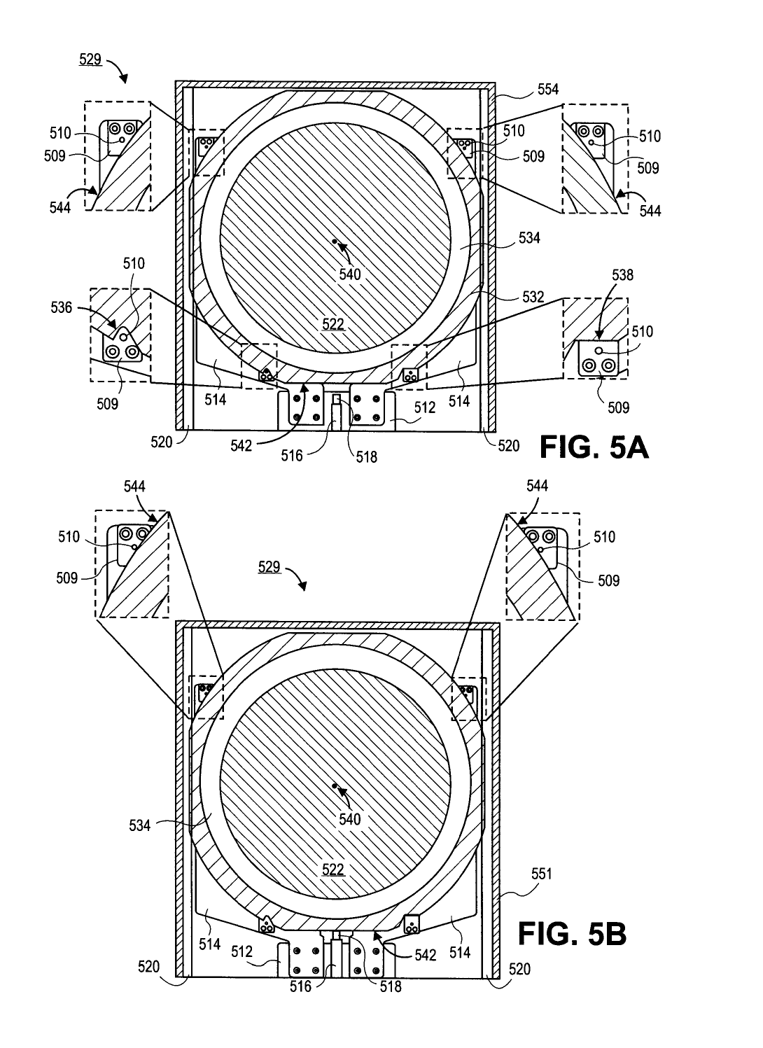

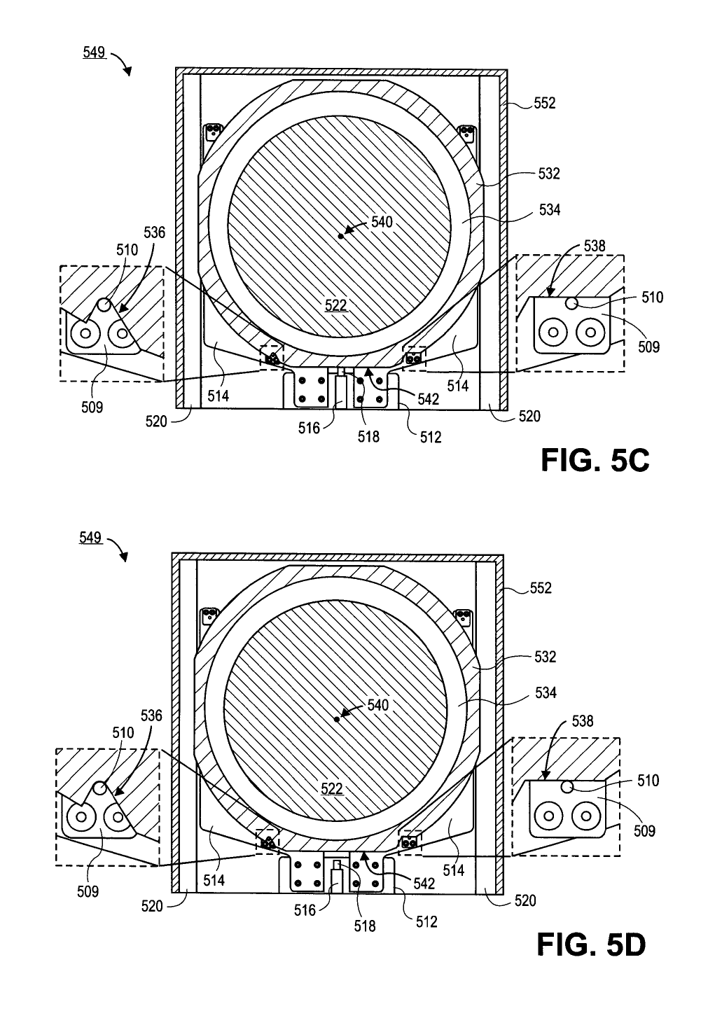

According to embodiments, a carrier ring is transferred from a first location to a second location with a robot arm that aligns the carrier ring during the transfer process. FIG. 4 includes a flowchart 400 representing operations in a process for transferring and aligning a carrier ring, according to an embodiment. FIGS. 5A-5D illustrate an overhead view of a robot arm 502 during performance of a process for transferring and aligning a carrier ring 532, corresponding to operations of flowchart 400, in accordance with an embodiment.

Referring now to operation 480 of flowchart 400, and corresponding FIG. 5A, the carrier ring 532 is lifted up from a first location by a robot arm 502. In an embodiment, the carrier ring 532 is lifted by the end effector 514 off of a slot 520 in a FOUP 529. According to an embodiment, the carrier ring 532 rests on the pads 509 of the dowel pin assembly 508. In an embodiment that does not include pads 509, the carrier ring 532 may rest directly on the end effector 514. In an embodiment, the carrier ring 532 is not in contact with any of the dowel pins 510. According to an embodiment, the plunger 516 may be retracted during the lifting process so that the gripping device 518 does not interact with the carrier ring 532.

Referring now to operation 482 of flowchart 400, and corresponding FIG. 5B, a plunger 516 is extended outwards from the end effector wrist 512 to contact the carrier ring 532. In an embodiment, the gripping device 518 attached to the plunger 516 contacts the carrier ring 532 along the bottom flat edge 542. In an embodiment contacting the carrier 532 also includes engaging the gripping device 518 such that the plunger 516 is securely coupled to the carrier ring 532. In embodiments that include a carrier ring 532 formed from a magnetic material, the gripping device 518 may be a magnetic gripping device. For example, the gripping device 518 may be an electromagnet or a permanent magnet. In embodiments that utilize an electromagnet, contacting the carrier ring 532 includes activating the electromagnet to produce a magnetic field that secures carrier ring 532 to the plunger 516. In an alternative embodiment the gripping device 518 may be a mechanical clamp. In such embodiments, contacting the carrier ring 532 with a mechanical clamp 518 includes contacting the carrier ring 532 and applying a clamping force to the bottom flat edge 542 of the carrier ring in order to secure the carrier ring 532 to the plunger 516. Once the plunger 516 is secured to the carrier ring 532, the carrier ring 532 can be displaced in the Y-direction by extending or retracting the plunger 516.

Referring now to operation 484 of flowchart 400, and corresponding FIG. 5B, after contacting the carrier ring 532, the plunger 516 is extended outwards away from the end effector wrist 512. Extension of the plunger 516 advances the carrier ring 532 away from the end effector wrist 512 until the carrier ring 532 engages the front dowel pins 510. In an embodiment, the carrier ring 532 engages the front dowel pins 510 along the rounded surfaces 544. Since both rounded surfaces 544 have the same radius and center point 540, contact along the rounded edges 544 allows for the location of the center point 540 of the carrier ring in the X and Y-directions to be known relative to the end effector 502. Additionally, the contact with the front dowel pins 510 and the plunger 516 provides three points of contact that secure the carrier ring 532 while it is being transferred to a second location.

Referring now to operation 486 of flowchart 400, the robot arm transfers the carrier ring 582 from a first location to a second location. In an embodiment, the second location may be a second storage device 549. For example, the second storage device may be another FOUP or a cassette. As shown in FIG. 5C, the second storage device 549 may include slots 520 for supporting the carrier ring 532. In an additional embodiment, the second location may be a processing tool. In such embodiments, the carrier ring 532 may be positioned over a chuck. Accordingly, the robot arm may align the center point 540 over the center of a chuck. Though flowchart 400 includes an operation describing the transfer of the carrier ring 532 from a first location to a second location, it is to be appreciated that the robot arm may perform only an alignment operation according to an embodiment. For example, if a carrier ring 532 is already located in the proper location (e.g., in a FOUP or on a chuck of a processing tool) but is misaligned, then the robot arm may be used solely to correct the alignment of the carrier ring 532. In such embodiments, the first and second locations may be the same location.

Referring now to operation 488 of flowchart 400, and corresponding FIG. 5C, the plunger 516 is retracted back towards the end effector wrist 512. Since the gripping device 518 is securely coupled to the carrier ring 532, the carrier ring 532 is also retracted. The plunger 516 retracts carrier ring 532 until the rear dowel pins 510 engage the alignment flat 538 and the alignment notch 536. The combination of an alignment flat 538 and an alignment notch 536 cause the carrier ring 532 to be aligned to a known angular position about the center point 540. In an embodiment, a carrier ring 532 that has an improper angular orientation will engage either the alignment flat 538 or the alignment notch 536 first as it is retracted. For example, the alignment notch 536 may engage a rear dowel pin before the alignment flat 538 engages a rear dowel pin 510. In such an embodiment, the carrier ring 532 will rotate about the alignment notch 536 until the alignment flat 538 engages a rear dowel pin 510. The rotation of the carrier ring 532 about the alignment notch 536 provides the proper angular orientation. Alternatively, the alignment flat 538 may engage a rear dowel pin first, and the carrier ring will rotate about the point of contact between the alignment flat 536 and the rear dowel pin 510 until the carrier ring is properly oriented. Over rotation beyond the aligned position is prevented because the Y-coordinates of the apex of the alignment notch 536 and the alignment flat 538 are substantially the same. Additionally, the notch 536 prevents the carrier ring 532 from moving in the X-direction. Accordingly, after the rear dowel pins 510 are engaged, the location of the center point 540 in the X and Y-directions, and the angular rotation of the carrier ring 532 about the center point 540 are known.

Referring now to operation 490 of flowchart 400, and corresponding FIG. 5D, the plunger 516 is detached from the carrier ring 532. In embodiments in which the gripping device 518 is a permanent magnet, detaching the plunger 516 from the carrier ring 532 includes retracting the plunger 516 back towards the end effector wrist 512 until the magnetic field of the gripping device 518 no longer interacts with the carrier ring 532. In embodiments in which the gripping device 518 is an electromagnet, detaching the plunger 516 from the carrier ring 532 includes switching off the electric current to the gripping device 518 in order to deactivate the magnetic field. Accordingly, embodiments with an electromagnetic gripping device 518 do not need to be physically detached from the carrier ring 532. In embodiments with a mechanical gripping device 518, detaching the plunger 516 from the carrier ring 532 may include releasing the clamping force from along the bottom flat edge 542 of the carrier ring. After detaching the plunger 516 from the carrier ring 532, the end effector 502 may place the oriented carrier ring 532 onto a second location. For example, the second location may include slots 520 in a second FOUP or cassette 529, or a chuck in a processing tool.

It is to be appreciated that the embodiments shown and described herein are exemplary in nature and the combinations and order of operations described are not limiting. For example, the process of retracting the plunger 516 and the carrier ring 532 until the rear dowel pins engage the alignment flat 538 and the alignment notch 536 may be implemented prior to transferring a carrier ring from a first location to a second location. Such embodiments may be utilized when the second location is a FOUP and the angular rotation of the carrier ring 532 about the center point 540 needs to be known prior to inserting the carrier ring 532 through a narrow opening. In additional embodiments, the process of retracting the plunger and the carrier ring may be implemented concurrently with the transfer process, or at an intermediate location between the first and second locations.

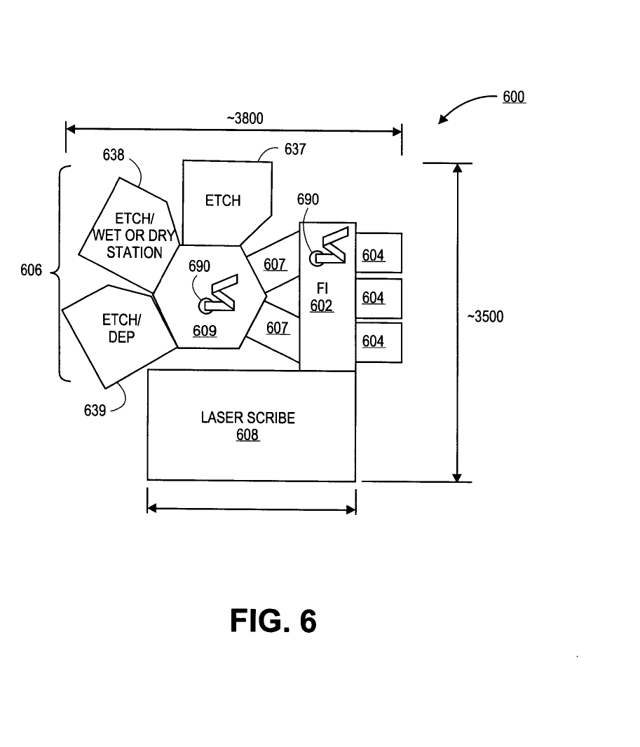

Referring now to FIG. 6, a process tool 600 that includes a wafer handling robot with an end effector according to an embodiment of the invention is shown. In an embodiment, a robot arm including an end effector wrist and an end effector, according to embodiments described herein, is attached to a robot 690 included in a factory interface 602. The process tool 600 may include a cluster tool 606 that is coupled to the factory interface 602 by one or more load locks 607. In an embodiment, a robot arm including an end effector wrist and an end effector, according to embodiments described herein, is attached to a robot 690 included in a transfer chamber 609. The robot 690 in the transfer chamber 609 may transfer carrier rings 532 between the load lock 607 and the one or more plasma etch chambers 637 included in the cluster tool 606. In an embodiment, the process tool 600 includes a laser scribe apparatus 608. A process tool 600 may be configured to perform a hybrid laser and etch singulation process of individual device dies formed on a substrate 522, such as a silicon wafer that is supported by a carrier ring 532.

In an embodiment, the laser scribe apparatus 608 houses a femtosecond-based laser. The femtosecond-based laser may be suitable for performing a laser ablation portion of a hybrid laser and etch singulation process of individual device dies formed on a substrate 522, such as a silicon wafer that is supported by a carrier ring 532. In one embodiment, a moveable stage is also included in the laser scribe apparatus 608, the moveable stage configured for moving a substrate 522 supported by a carrier ring 532 relative to the femtosecond-based laser. In another embodiment, the femtosecond-based laser is also moveable.

In an embodiment, the one or more plasma etch chambers 637 in the cluster tool 606 may be suitable for performing an etching portion of a hybrid laser and etch singulation process of individual device dies formed on a substrate 522, such as a silicon wafer that is supported by a carrier ring 532. An etch chamber may be configured for etching a substrate 522 supported by a carrier ring 532 through the gaps in a patterned mask. In one such embodiment, the one or more plasma etch chambers 637 in the cluster tool 606 is configured to perform a deep silicon etch process. In a specific embodiment, the one or more plasma etch chambers is an Applied Centura® Silvia™ Etch system, available from Applied Materials of Sunnyvale, Calif., USA. The etch chamber may be specifically designed for a deep silicon etch used to singulated integrated circuits housed on or in single crystalline silicon substrates or wafers. In an embodiment, a high-density plasma source is included in the plasma etch chamber to facilitate high silicon etch rates.

In an embodiment, the factory interface 602 may be a suitable atmospheric port to interface with the load ports 604 and with the laser scribe tool 608 and the cluster tool 606. The factory interface 602 may include one or more robots 690, such as ones with robot arms in accordance with embodiments described herein, for transferring carrier rings 532 from the load ports 604 into either load locks 607 or laser scribe apparatus 608, or both.

Cluster tool 606 may include other chambers suitable for performing functions in a method of singulation. For example, in one embodiment, in place of an additional etch chamber, a deposition chamber 639 is included. The deposition chamber 639 may be configured for mask deposition on or above a device layer of a wafer or a substrate prior to laser scribing of the wafer or substrate. In one such embodiment, the deposition chamber 639 is suitable for depositing a water soluble mask. In another embodiment, in place of an additional etch chamber, a wet/dry 638 station is included. The wet/dry station 638 may be suitable for cleaning residues and fragments, or for removing a water soluble mask, subsequent to a laser scribe and plasma etch singulation process of a substrate or a wafer. In an embodiment, a metrology station is also included as a component of process tool 600.

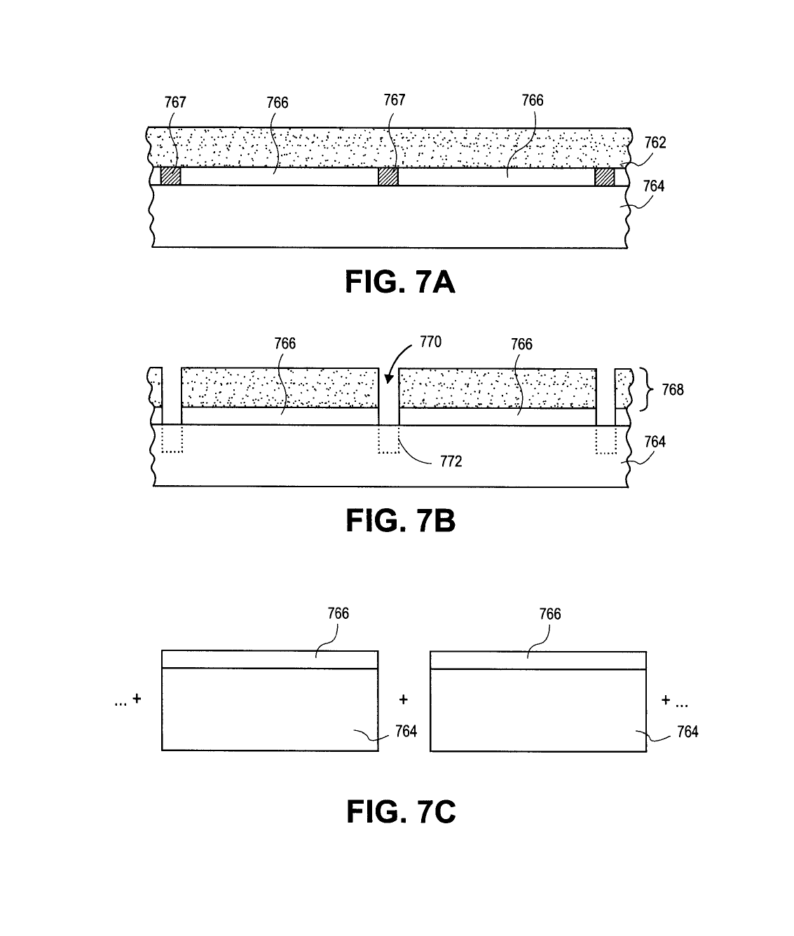

According to an embodiment, a hybrid laser and etch singulation process may include a process such as the one illustrated in FIGS. 7A-7C. Referring to FIG. 7A, a mask 762 is formed above a semiconductor wafer or substrate 764. The mask 762 is composed of a layer covering and protecting integrated circuits 766 formed on the surface of semiconductor wafer 764. The mask 762 also covers intervening streets 767 formed between each of the integrated circuits 766.

Referring to FIG. 7B, the mask 762 is patterned with a laser scribing process to provide a patterned mask 768 with gaps 770, exposing regions of the semiconductor wafer or substrate 764 between the integrated circuits 766. As such, the laser scribing process is used to remove the material of the streets 767 originally formed between the integrated circuits 766. In accordance with an embodiment of the present invention, patterning the mask 762 with the laser scribing process further includes forming trenches 772 partially into the regions of the semiconductor wafer 764 between the integrated circuits 366, as depicted in FIG. 7B.

Referring to FIG. 7C, the semiconductor wafer 764 is etched through the gaps 770 in the patterned mask 768 to singulate the integrated circuits 766. In accordance with an embodiment of the present invention, etching the semiconductor wafer 764 includes ultimately etching entirely through semiconductor wafer 764, as depicted in FIG. 7C, by etching the trenches 772 initially formed with the laser scribing process. In one embodiment, the patterned mask 768 is removed following the plasma etching, as is also depicted in FIG. 7C.

Accordingly, referring again to FIGS. 7A-7C, wafer dicing may be performed by initial ablation using a laser scribing process to ablate through a mask layer, through wafer streets (including metallization) and, possibly, partially into a substrate or wafer. Die singulation may then be completed by subsequent through-substrate plasma etching, such as through-silicon deep plasma etching.

Embodiments of the present invention may be provided as a computer program product, or software, that may include a machine-readable medium having stored thereon instructions, which may be used to program a computer system (or other electronic devices) to perform a process according to embodiments of the present invention. In one embodiment, the computer system is coupled with robot arm 302 described in association with FIG. 3 or a process tool 600 described in association with FIG. 6. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

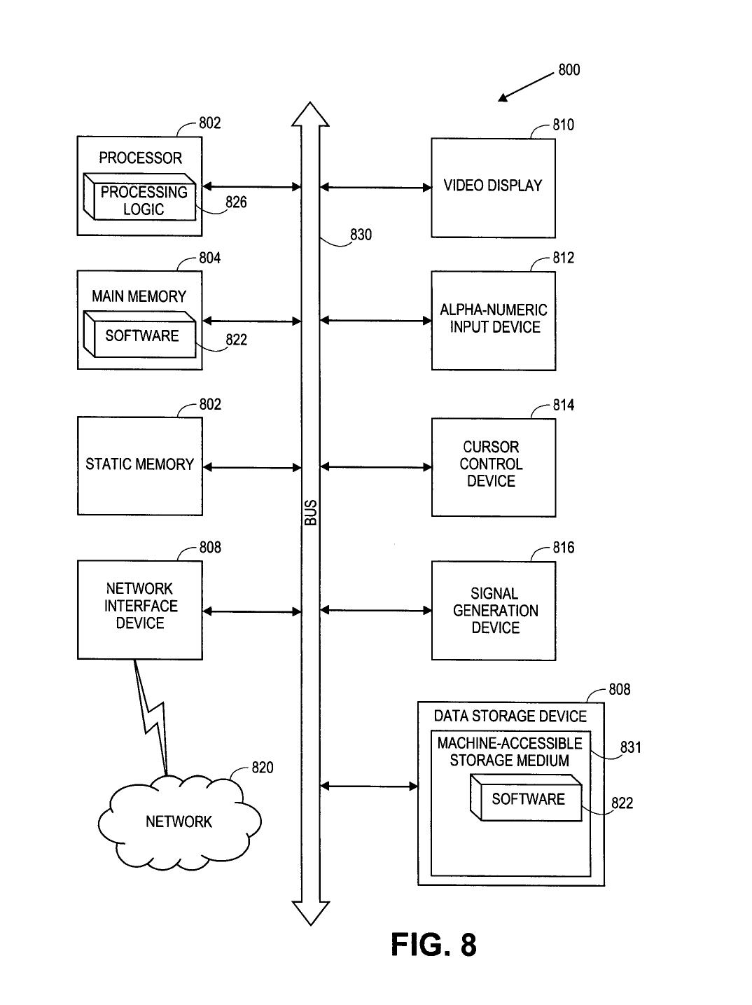

FIG. 8 illustrates a diagrammatic representation of a machine in the exemplary form of a computer system 800 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 800 includes a processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

Processor 802 represents one or more general-purpose processing devices such as a microprocessor, central processing unit, or the like. More particularly, the processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. Processor 802 is configured to execute the processing logic 826 for performing the operations described herein.

The computer system 800 may further include a network interface device 808. The computer system 800 also may include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium (or more specifically a computer-readable storage medium) 831 on which is stored one or more sets of instructions (e.g., software 822) embodying any one or more of the methodologies or functions described herein. The software 822 may also reside, completely or at least partially, within the main memory 804 and/or within the processor 802 during execution thereof by the computer system 800, the main memory 804 and the processor 802 also constituting machine-readable storage media. The software 822 may further be transmitted or received over a network 820 via the network interface device 808.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

In accordance with an embodiment of the present invention, a machine accessible storage medium has instructions stored thereon which cause a data processing system to perform a method of transferring and aligning a carrier ring. The method involves lifting the carrier ring up from a first location with a robot arm. The method also involves contacting the carrier ring with a plunger. The plunger includes a gripping mechanism that securely couples the carrier ring to the plunger. The method also involves extending the plunger until the carrier ring contacts the front dowel pins on an end effector. The method may also include transferring the carrier ring from a first location to a second location with the robot arm. The method includes retracting the plunger and the carrier ring until the rear dowel pins on the end effector engage the alignment flat and the alignment notch. The method also includes detaching the plunger from the carrier ring. The method may also include placing the oriented carrier ring on the second location with the end effector.

1. A method of aligning a carrier ring comprising:
lifting the carrier ring from a first location with an end effector coupled to an end effector wrist, wherein the end effector has front dowel pins and rear dowel pins, and the end effector wrist includes a plunger;
contacting the carrier ring with the plunger;
extending the plunger until the carrier ring contacts the front dowel pins; and
retracting the plunger and the carrier ring until the carrier ring contacts the rear dowel pins.

2. The method of claim 1, wherein the plunger includes a gripping device, and wherein contacting the carrier ring includes securing an edge of the carrier ring to the plunger with the gripping device.

3. The method of claim 2, wherein the carrier ring is formed from a magnetic material and wherein the gripping device is a magnet.

4. The method of claim 3, wherein the magnet is an electromagnet.

5. The method of claim 1, wherein the carrier ring includes an alignment notch and an alignment flat, and wherein retracting the plunger and the carrier ring includes contacting a first rear dowel pin with an apex of the alignment notch and contacting a second rear dowel pin with the alignment flat.

6. The method of claim 1, further comprising transferring the carrier ring from a first location to a second location after extending the plunger until the carrier ring contacts the two front dowel pins.

7. The method of claim 6, wherein the first location is a front opening unified pod (FOUP) and the second location is a processing tool.

8. The method of claim 6, wherein the first location is a processing tool and the second location is a FOUP.

9. The method of claim 6, wherein the first location and the second location are the same location.

10. A robot arm comprising:
an end effector extending out from an end effector wrist, wherein rear dowel pins are positioned on the end effector proximate to the end effector wrist, and front dowel pins are positioned on the end effector proximate to the opposite end of the end effector; and
a plunger that is extendable out from the end effector wrist, wherein the plunger includes a gripping device.

11. The robot arm of claim 10, wherein the gripping device is a magnet.

12. The robot arm of claim 11, wherein the magnet is an electromagnet.

13. The robot arm of claim 10, wherein the gripping device is mechanical gripping device.

14. The robot arm of claim 10, wherein the gripping device and the plunger are a single component.

15. The robot arm of claim 10, wherein each of the rear dowel pins and the front dowel pins extend upwards from a pad coupled to the end effector.

16. The robot arm of claim 10, further comprising a wafer handling robot coupled to the robot arm.

17. The robot arm of claim 10, wherein the rear dowel pins have a radius that is approximately equal to the radius of curvature of an apex of an alignment notch on a carrier ring.

18. The robot arm of claim 17, wherein the rear dowel pins have a radius that is approximately 1.5 mm or greater.

19. The robot arm of claim 10, wherein the plunger is a hydraulic piston.

20. A method of aligning a carrier ring comprising:
lifting the carrier ring from a first location with an end effector that is coupled to an end effector wrist, wherein front dowel pins and rear dowel pins are coupled to the end effector, and wherein the end effector wrist has a plunger that includes a gripping device that is extendable out from the end effector wrist;
contacting an edge of the carrier ring with the plunger;
securing the plunger to the edge of the carrier ring with the gripping device;
extending the plunger out from the end effector wrist until the carrier ring contacts the two front dowel pins;
transferring the carrier ring from the first location to the second location;
retracting the plunger and the carrier ring until a first rear dowel pin engages an alignment notch on the carrier ring and a second rear dowel pin engages an alignment flat on the carrier ring; and
placing the carrier ring on the second location.
